(19) United States
(12) Patent Application Publication
(10) Pub. No.: US 2013/0299764 A1
(43) Pub. Date: Nov. 14, 2013

(54) LOCALIZED DEVICE

(71) Applicants: Shyue Seng TAN, Singapore (SG); Eng Huat TOH, Singapore (SG); Elgin QUEK, Singapore (SG)

(72) Inventors: Shyue Seng TAN, Singapore (SG); Eng Huat TOH, Singapore (SG); Elgin QUEK, Singapore (SG)

(73) Assignee: GLOBALFOUNDRIES Singapore Pte. Ltd., Singapore (SG)

(21) Appl. No.: 13/469,103

(22) Filed: May 11, 2012

(51) Int. Cl. H01L 45/00; H01L 21/8239

(52) U.S. Cl. 257/2; 438/382; 257/E21.645; 257/E21.004; 257/E45.001

(57) ABSTRACT

A device is disclosed. The device includes a gate disposed on a substrate in a device region, the gate having first and second sidewalls. The gate includes a gate electrode and a resistive layer disposed between the gate electrode and substrate. First doped regions of a first polarity type are disposed in the substrate adjacent to the first and second sidewalls of the gate. The gate overlaps the first doped regions by a first distance to form overlap portions. A portion of the resistive layer between the gate electrode and overlap portions form first and second storage elements of a multi-bit resistive memory cell.

### BACKGROUND

Non-volatile memory (NVM) has achieved widespread adoptions for code and data storage applications. One type of NVMs is Resistive Random Access Memory (RRAM) which demonstrates an attractive storage concept combining fast operation and high densities. However, the applications of RRAM are limited by, for example, poor memory margin caused by poor resistance uniformity.

Therefore, it is desirable to provide a more reliable RRAM which gives improved memory margin.

### SUMMARY

A device is disclosed. The device includes a gate disposed on a substrate in a device region, the gate having first and second sidewalls. The gate includes a gate electrode and a resistive layer disposed between the gate electrode and substrate. First doped regions of a first polarity type are disposed in the substrate adjacent to the first and second sidewalls of the gate. The gate overlaps the first doped regions by a first distance to form overlap portions. A portion of the resistive layer between the gate electrode and overlap portions form first and second storage elements of a multi-bit resistive memory cell.

In another embodiment, a method of forming a device is presented. The method includes providing a substrate and forming a gate disposed on the substrate. The gate has first and second sidewalls, a gate electrode and a resistive layer disposed between the gate electrode and substrate. First doped regions of a first polarity type are formed in the substrate adjacent to the first and second sidewalls of the gate. The first doped regions overlap the gate by a first distance to form overlap portions. A portion of the resistive layer between the gate electrode and overlap portions form first and second storage elements of a multi-bit resistive memory cell.

In yet another embodiment, a device is disclosed. The device includes a substrate prepared with a feature thereover. The feature includes a top electrode over a resistive layer. The device also includes a doped region in the substrate adjacent to the feature. The doped region partially overlaps the resistive layer and serves as a bottom electrode. The overlapping area is small enough to form low number of conduction paths in the resistive layer when an appropriate voltage is applied.

These and other objects, along with advantages and features of the present invention herein disclosed, will become apparent through reference to the following description and the accompanying drawings. Furthermore, it is to be understood that the features of the various embodiments described herein are not mutually exclusive and can exist in various combinations and permutations.

### BRIEF DESCRIPTION OF THE DRAWINGS

In the drawings, like reference characters generally refer to the same parts throughout the different views. Also, the drawings are not necessarily to scale, emphasis instead generally being placed upon illustrating the principles of the invention. In the following description, various embodiments of the present invention are described with reference to the following drawings, in which:

FIG. 1 shows an embodiment of a memory cell;

FIG. 2 shows an embodiment of a memory array;

FIG. 3 shows a cross-sectional view of an embodiment of a memory cell;

FIG. 4 shows a top view of a portion of an embodiment of a memory cell;

FIGS. 5a-g show an embodiment of a process for forming a memory cell; and

FIGS. 6a-b show plan views of a process for forming memory cells.

### DETAILED DESCRIPTION

Embodiments generally relate to semiconductor devices. Some embodiments relate to memory devices, such as NVM devices. More particularly, some embodiments relate to RRAM devices. Such memory devices, for example, can be incorporated into standalone memory devices, such as USB or other types of portable storage units, or ICs, such as microcontrollers or system on chips (SoCs). The devices or ICs can be incorporated into or used with, for example, consumer electronic products, such as computers, cell phones, and personal digital assistants (PDAs).

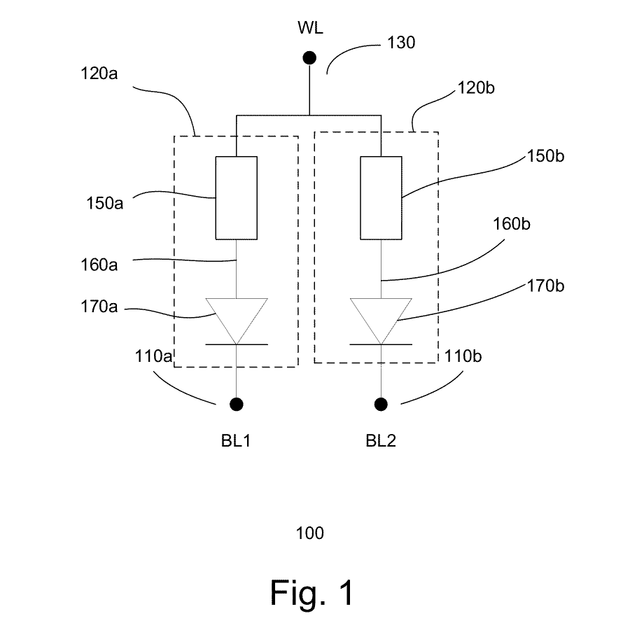

FIG. 1 shows a schematic diagram of an embodiment of a device. In one embodiment, the device includes a memory cell 100. The memory cell, in one embodiment, includes a non-volatile memory cell. In one embodiment, the NVM memory cell is an RRAM cell. In one embodiment, the NVM memory cell is a multi-bit RRAM cell. A multi-bit RRAM cell is capable of storing a plurality of bits of data. In one embodiment, the multi-bit RRAM cell is a dual bit RRAM cell which stores two bits of data. Providing other types of memory cell configurations or structures may also be useful.

In one embodiment, the dual-bit RRAM cell includes a wordline terminal 130 and first and second bitline terminals 110a-b. The wordline terminal is coupled to a wordline WL and the bitline terminals are coupled to first and second bitlines BL1 and BL2. The memory cell includes a first bit 120a disposed between wordline terminal and the first bitline terminal and a second bit 120b disposed between the wordline terminal and the second bitline terminal. The wordline terminal, for example, serves as a common top electrode of the bits of the memory cell. A bit includes a resistor and a diode coupled in series between the wordline terminal and a bitline terminal of the memory cell while a bottom electrode commonly couples the resistor to the diode. For example, the first bit includes a first resistor 150a, a first bottom electrode 160a and a first diode 170a coupled in series between the wordline terminal and the first bitline terminal and the second bit includes a second resistor 150b, a second bottom electrode and a second diode 170b coupled in series between the wordline terminal and the second bitline terminal. In one embodiment, a resistor is coupled to a wordline while a cathode of a diode is coupled to a bitline terminal. The anode of the diode is coupled to the resistor. As such, a bit of the cell is configured in a one diode-one resistor (1D1R) structure. Other types of bit or cell structures may also be useful.

A resistor of a bit, in one embodiment, is formed of a programmable resistive material. The programmable resistive material can be in a first or second resistive state. In one embodiment, the first state is a high resistive state and the second state is a low resistive state. One of the resistive state represents a logic “0” while the other represents a logic “1”. For example, the high resistive state may represent a logic 0 while the low resistive state may represent a logic 1. Having the high resistive state representing a logic 1 and the low resistive state representing a logic 0 may also be useful. Other configurations of data storage for the RRAM may also be useful.

In one embodiment, the programmable resistive material includes a transitional metal oxide, such as titanium oxide (TiOₓ), nickel oxide (NiOx), aluminum oxide (AlOx), hafnium oxide (HfOx), tungsten oxide (WOx), tantalum oxide (TaOx), vanadium oxide (VOx), and copper oxide (CuOx). Other types of programmable resistive materials may also be useful. A programmable resistive material is subjected to a forming procedure which creates conduction paths or filaments after it is formed. The filaments can be reset or broken by subjecting the programmable resistive material to a reset procedure or condition; the filaments can be set or re-formed by subjecting the programmable resistive material to a set procedure or condition. Once set or reset, the state of the resistor is stable until reset or set. A resistor with broken filaments is in a high resistive state while a reset resistor with re-formed filaments is in a low resistive state.

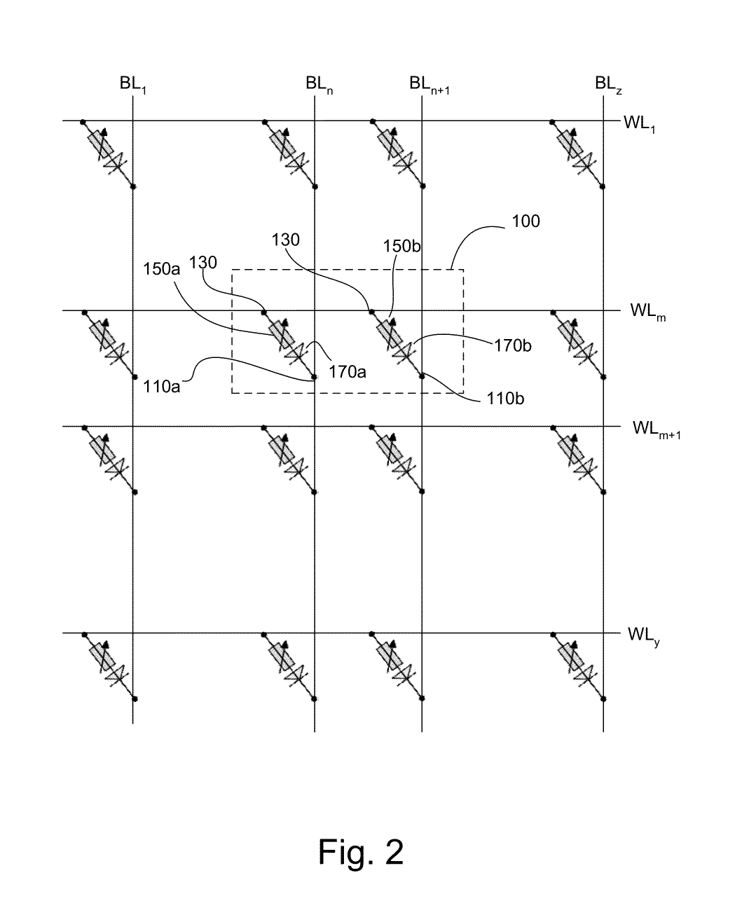

A plurality of RRAM cells are interconnected by wordines and bitlines to form a memory array. FIG. 2 shows an embodiment of a memory array 200 being a y×z array, with wordlines WL₁-WL_{y} and bitlines BL₁-BL₂. Wordlines may correspond to rows of memory cells of the array while bitlines correspond to columns of the array. As discussed, a memory cell 100 is a dual-bit memory cell. For example, a memory cell includes first and second bits 120a-b configured in a 1R1D structure which includes a resistor and a diode coupled in series. For example, the first bit includes a first resistor 150a and a first diode 170a and the second bit includes a second resistor 150b and a second diode 170b. The resistor and diode are coupled in series between a wordline and a bitline. The resistor is coupled to a wordline and the diode is coupled to a bitline. The bits of a memory cell are coupled to adjacent bitlines, for example, bitlines BLₙ and BLₙ₊₁ and a common wordline, such as WLₘ.

A bit may be selected for accessing by providing the appropriate voltages to wordlines and bitlines of the memory array. When a bit is selected, its respective diode is forward biased, allowing current to flow through the selected bit. In contrast, the diode of an unselected bit is reverse biased. This prevents current from flowing through an unselected bit. The array may be configured to access multiple bits of multiple cells simultaneously. Furthermore, the array may be sub-divided into a plurality of blocks of memory cells. Other configurations of arrays and/or accessing cells in the array may also be useful.

A bit access may include different types of memory operations of an RRAM. For example, a bit access may include forming, read, set and reset operations. Table 1a shows the various signals applied to the terminals of the memory cell, depending on the desired operation and bit to access.

TABLE 1a

| Operation | |
|---|---|
| BL | WL |

| | Sel. | Un-sel. | Sel | Un-sel. |
|---|---|---|---|---|
| Forming | V_{form} | Float | Vₛₑₗ | Float |
| Read | V_{read} | Float | Vₛₑₗ | Float |
| Set | Vₛₑₜ | Float | Vₛₑₗ | Float |
| Reset | Vᵣₑₛₑₜ | Float | Vₛₑₗ | Float |

Table 1b shows an embodiment of the values for the different signals applied to the terminals of a memory cell.

TABLE 1b

| Signal | V_{form} | V_{read} | Vₛₑₜ | Vᵣₑₛₑₜ | Vₛₑₗ |
|---|---|---|---|---|---|
| Value | 14 | 0.5 | 4 | 1.5 | 1 |

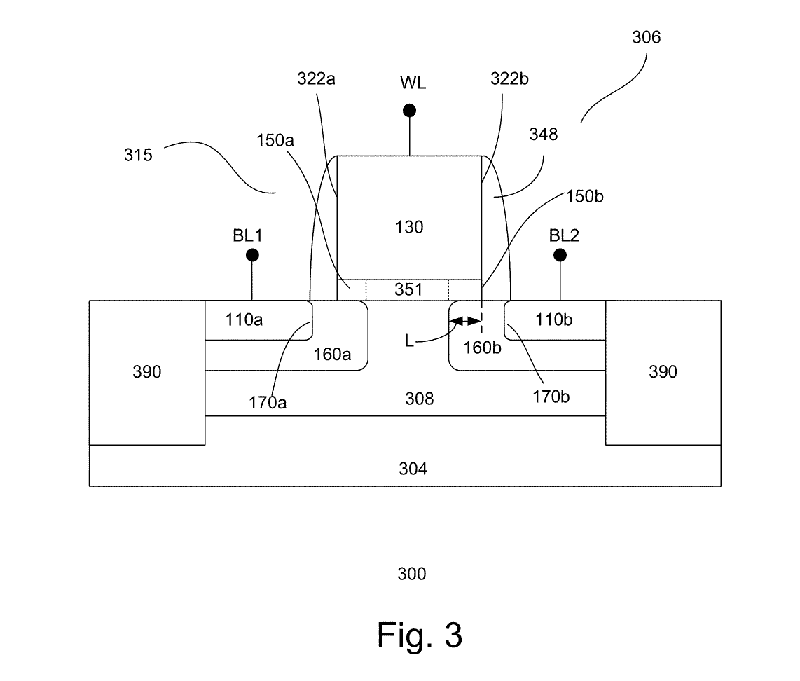

FIG. 3 illustrates a cross-sectional view of an embodiment of a device 300. In one embodiment, the device is a RRAM cell. The memory cell, as shown, is a multi-bit RRAM cell. The memory cell, in one embodiment, is a dual-bit RRAM cell. In one embodiment, the dual-bit memory cell corresponds to a dual-bit RRAM cell, as described in FIG. 1. As such, common elements may not be described or described in detail.

A substrate 304 is shown which includes a device region 306. The device region, in one embodiment, is a cell region, in which a memory cell 300 is disposed. The substrate, for example, is a silicon substrate. The substrate, for example, can be a lightly doped substrate. The substrate may be lightly doped with p-type dopants. Providing other types of substrates may also be useful. For example, the substrate may be doped with n-type dopants and/or other dopant concentrations, including intrinsically doped substrates. In other embodiments, the substrate may a semiconductor-on-insulator substrate, such as silicon-on-insulator (SOI) or germanium-on-isolator substrates. A semiconductor-on-insulator substrate includes a surface and bulk semiconductor layers separated by an insulator, such as silicon oxide. The semiconductor layers may be doped or undoped. Additionally, it is understood that the different semiconductor layers (e.g., surface and bulk) need not be of the same type of semiconductor materials.

An isolation region 390 may be provided for isolating the cell region from, for example, other device regions of the substrate. The isolation region may isolate other cell regions of an array region as well as other device regions. For example, the isolation region may be provided along the column direction to separate columns of the memory cells. In one embodiment, the isolation region is a shallow trench isolation (STI) region. An STI, for example, includes an isolation or dielectric material, such as silicon oxide, in a trench which surrounds the device region. The STI may have a depth and width sufficient to provide isolation from one device region to another. For example, the STI may have a depth of about 300 nm and a width of about 80 nm. Other dielectric materials or dimensions may also be useful for the STI. Alternatively, other types of isolation regions may also be employed. For example, the isolation region may be a deep trench isolation (DTI) region which is deeper than an STI.

In one embodiment, the memory cell includes a gate 315 having a gate electrode 130 over a programmable resistive layer 351. The gate electrode may serve as a top electrode of the memory cell. The gate electrode is coupled to a wordline WL. The gate electrode, for example, may be polysilicon. Other types of gate electrode materials, such as metal or metal nitride, are also useful. Various types of metals, such as Ti, Cu, Ta and W, can be used. Other types of gate electrode materials may also be useful. Furthermore, the gate electrode 130 may be doped with dopants. The gate electrode, for example, may be doped with the same dopant type of the memory cell type to reduce resistance, adjust V_{T}, adjust work function or a combination thereof. Doping the gate electrode with other dopant types is also useful.

The programmable resistive layer can be put in a first or second resistive state. The programmable resistive layer remains in a stable state until switched to the other state. In one embodiment, the programmable resistive layer is formed from a material which, when conductions paths are formed, can be broken (reset) or reformed (set) to be in a first or second resistive state. In one embodiment, when the conduction paths are formed or reformed in the resistive material, it is in a first or low resistive state which corresponds to a logic “1” stored; when the conduction paths are broken or set, the resistive material is in a second or high resistive state which corresponds to a logic “0” stored. Other configurations of resistive states and data stored in the resistive layer may also useful.

In one embodiment, the programmable resistive material includes a transitional metal oxide, such as TiOₓ, NiOx, AlOx, HfOx, WOx, TaOx, VOx, and CuOx. Other types of programmable resistive materials may also be useful. A programmable resistive material is subjected to a forming procedure which creates conduction paths or filaments after it is formed.

Sidewalls of the gate can be provided with sidewall spacers 348. The sidewall spacers, for example, are formed of a dielectric material, such as silicon oxide. Other types of dielectric materials, such as silicon nitride, or a combination of dielectric materials may also be useful. The sidewall spacers, for example, facilitate displacing the second doped regions from the gate sidewalls. The thickness of the spacers, for example, may be about 10-30 nm. Other thicknesses may also be useful.

First doped regions 160a-b are disposed in the substrate adjacent to sidewalls of the gate. The first doped regions are disposed in the device region adjacent to first and second gate sidewalls 322a-b. The first doped regions serve as bottom electrodes of first and second bits of the memory cell. The first doped regions include first polarity type dopants. In one embodiment, the first doped regions are lightly doped with first polarity type dopants. The concentration of the first doped regions may be about 1E13-1E15 cm⁻³. Other dopant concentrations may be useful. The first polarity type dopant, in one embodiment, is p-type. Providing first polarity type dopants which are n-type may also be useful. The depth of the first doped regions, for example, may be about 150 nm. Providing other depths for the first doped regions may also be useful. N-type dopants can include phosphorus (P), arsenic (As), antimony (Sb) or a combination thereof while p-type dopants can include boron (B), indium (In) or a combination thereof.

In accordance with one embodiment, the first doped regions and the gate overlap, forming overlap regions L. For example, the gate electrode overlaps the first doped region 160a adjacent to a first gate sidewall and the first doped region 160b adjacent to a second gate sidewall. The overlap region L of a first doped region defines about a width of a resistor of a bit of the memory cell. The overlap region of the first doped region 160a adjacent to the first gate sidewall defines about a width of a first resistor 150a of the first bit of the memory cell in the resistive layer; the overlap region of the first doped region 160b adjacent to the second gate sidewall defines about a width of a second resistor 150b of the second bit of the memory cell in the resistive layer.

In one embodiment, L is sufficiently small or narrow to limit the amount of filaments formed in the resistor portion of the resistive layer to a small number to improve resistance distribution of memory bits. The smaller the L is, the smaller the number of filament current paths that are formed in the resistor. In one embodiment, L is about 1-10 nm in length, as measured from the edge of the first doped region and the gate sidewall which overlaps that first doped region. Such a width limits a low number of filaments to be formed in the resistor portion of the resistive layer. In one embodiment, L is selected to limit the number of filaments formed to about 1-2. Providing L which limits other low number of filaments in the resistor portion of the resistive layer may also be useful.

As described, the overlap regions produce localized resistors in a resistive layer. This results in a low number of filaments in a resistor which advantageously improves resistance distribution of memory cells of the array. Additionally, the overlap regions produce a multi-bit memory cell from a common resistive layer, facilitating a lower bit per area layout.

Second doped regions 110a-b are disposed in the substrate adjacent to the sides of the gate. The second doped regions include second polarity type dopants. For example, the second doped region has the opposite dopant type as the first doped regions. In one embodiment, the second doped regions are heavily doped with second polarity type dopants. For example, the second doped regions are heavily doped n-type regions for the case where the first doped regions are p-type regions. The dopant concentration of the second doped regions may be about 1E13-1E15 cm³. Providing other dopant concentrations for the second doped regions may also be useful.

In an alternative embodiment, the second doped regions are disposed on the surface of the substrate adjacent to the sides of the gate. The second doped regions, for example, include doped epitaxial layers disposed on the substrate adjacent to the sides of the gate. The second doped regions may be raised doped regions. For example, the raised doped regions have a top surface above the substrate surface. Providing non-raised doped regions may also be useful. In some embodiments, the epitaxial doped layers may be disposed in trenches adjacent to the sides of the gate. The epitaxial doped layer may be an insitu doped epitaxial layer. In other embodiments, the epitaxial doped layers may be implanted with second polarity type dopants.

The second doped regions, in one embodiment, are displaced from the sides of the gate. For example, a second doped region 110a is displaced from the first gate sidewall and a second doped region 110b is displaced from the second gate sidewall. In one embodiment, the second doped regions are displaced from the gate sidewalls by about 1-10 nm. Other displacements of the second doped regions from the gate sidewalls may also be useful.

The second doped regions are displaced from the gate. For example, the second doped regions are displaced from the sidewalls of the gate by about the width of the sidewall spacers. The second doped regions may be overlapped by the spacers slightly due to diffusion of dopants from annealing or subsequent thermal processes. However, the second doped regions are not overlapped by the gate.

The second doped regions are disposed in the device region of the substrate within the first doped regions. For example, a depth of the second doped regions is shallower than the depth of the first doped regions. The depth of the second doped region may be about 10-50 nm. In one embodiment, the depth of second doped regions is about 20 nm. The interfaces of the first and second doped regions form PN junctions which serve as the first and second diodes 170a-b of the bits of the memory cell.

The surface of the gate electrode and second doped regions may be provided with metal silicide contacts (not shown). The metal silicide contacts, for example, may be nickel based metal silicide contact. Other types of metal silicide contacts may also be useful. The metal silicide contacts facilitate reduced contact resistance.

As shown, a deep well 308 may be provided in the substrate, encompassing the first and second doped regions. In one embodiment, the deep well includes dopants of the same polarity type as the second doped regions 110a-b. In one embodiment, the deep well includes dopants of second polarity type dopants. For example, the deep well includes dopants of the opposite polarity type than the first doped regions. The deep well may serve as a device well to isolate the components of the memory cell, such as the first and second doped regions from the substrate. For example, the deep well may be n-doped. For example, the dopant concentration of the deep well may be 1E12-1E13 cm⁻³. Other dopant concentrations for the deep well may also be useful. The deep wells of different cells may be isolated by the isolation regions.

The gate, in one embodiment, is an individual gate disposed in the cell region. For example, the gate is not a gate conductor which serves as a common gate with other memory cells. The gates of memory cells may be coupled by, for example, a wordline WL. In one embodiment, isolation regions are provided along the bitline direction of the cell region to isolate bitline terminals of adjacent memory cells. Isolation regions are also provided to isolate gates of adjacent memory cells in a wordline direction. The bitline terminals are common bitline terminals of adjacent memory cells in the bitline direction. Other configurations of gates, bitline terminals and isolation regions may also be useful.

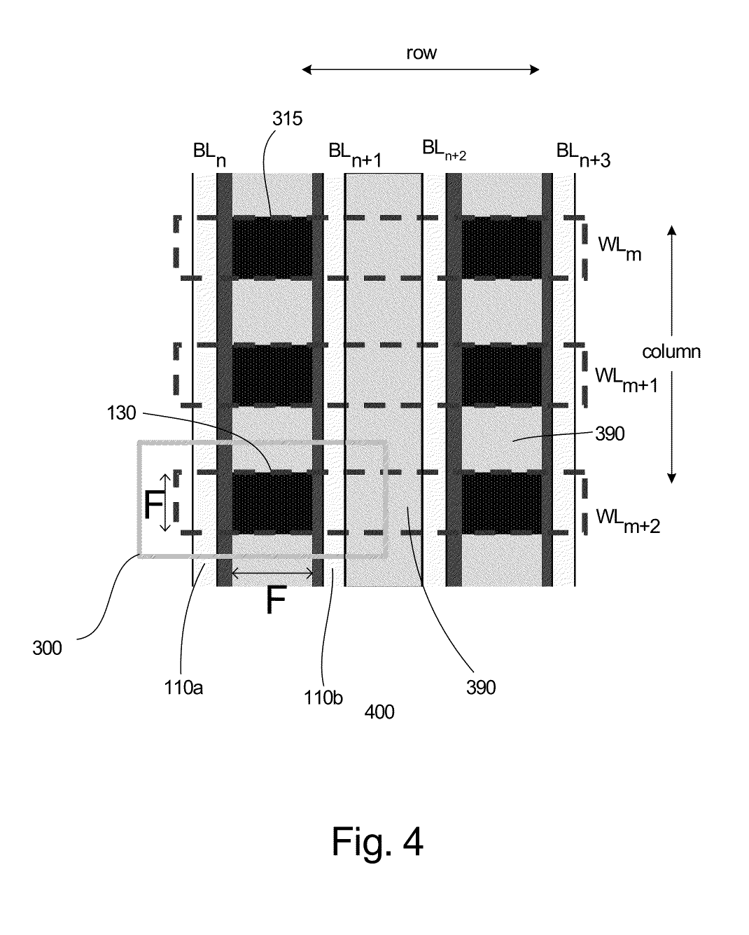

A plurality of RRAM cells are interconnected by wordines and bitlines to form a memory array. FIG. 4 shows a plan view of a layout of a portion 400 of an embodiment of a memory array 400 having a plurality of memory cells 300. The memory array includes RRAM cells, as described in FIG. 3. As such, common elements may not be described or described in detail.

As shown, the memory cells are arranged in a matrix having columns and rows of memory cells. The memory cells, in one embodiment, includes individual gates 315 in both row and column directions, as indicated by arrows. Bitline terminals 110a-b extend along the column direction and form common bitline terminals of memory cells along the column direction. The column and row directions, for example, may be orthogonal to each other. Providing non-orthogonal column and row directions may also be useful. In one embodiment, isolation regions isolate bitline terminals of adjacent columns of memory cells and also isolate gates of adjacent memory cells in the row direction.

The gates in the row direction are coupled by wordlines. For example, gates of a common row are coupled by a wordline. As shown, gates are coupled by wordlines Wₘ, Wₘ₊₁ and Wₘ₊₂ (shown by dotted line) in the row direction. Bitline terminals are coupled to bitlines in the column direction. As shown, bitline terminals are coupled to bitlines BLₙ, BLₙ₊₁, BLₙ₊₂ and BLₙ₊₃. Since a bitline terminal is a common bitline terminal of a column of cells, only one contact need to be formed between a bitline terminal and a bitline. In some cases, multiple bitline contacts may be provided to switch a bitline to a bitline terminal. The row and column directions are orthogonal to each other. Other configurations of bitlines and wordlines may also be useful. A bit may be selected for accessing by providing appropriate voltages to wordlines and bitlines of the memory array, as described in Tables 1a-b.

In one embodiment, the unit cell of the cell layout has a unit cell size of 8F², where F is the feature size. For the case where a unit cell has 2 bits, an effective bit area of about 4F² is achieved. Other cell layouts or cell/bit sizes may also be useful.

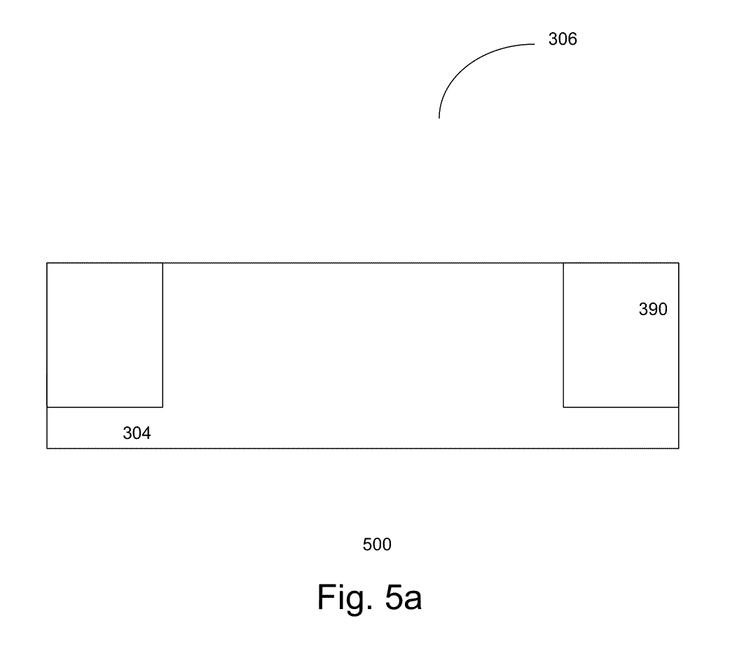

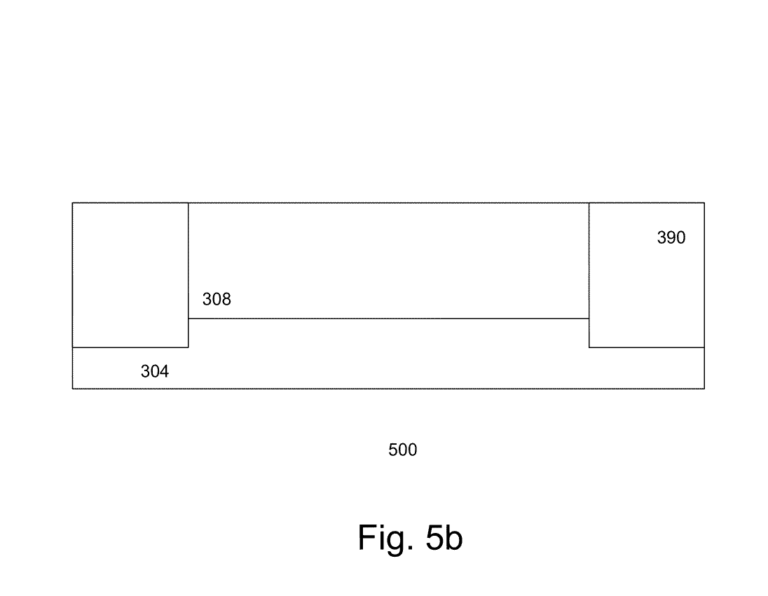

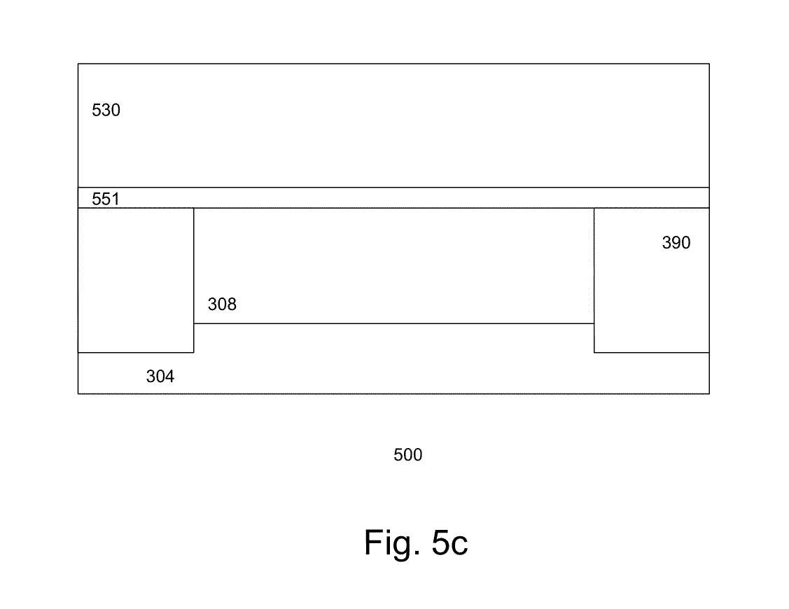

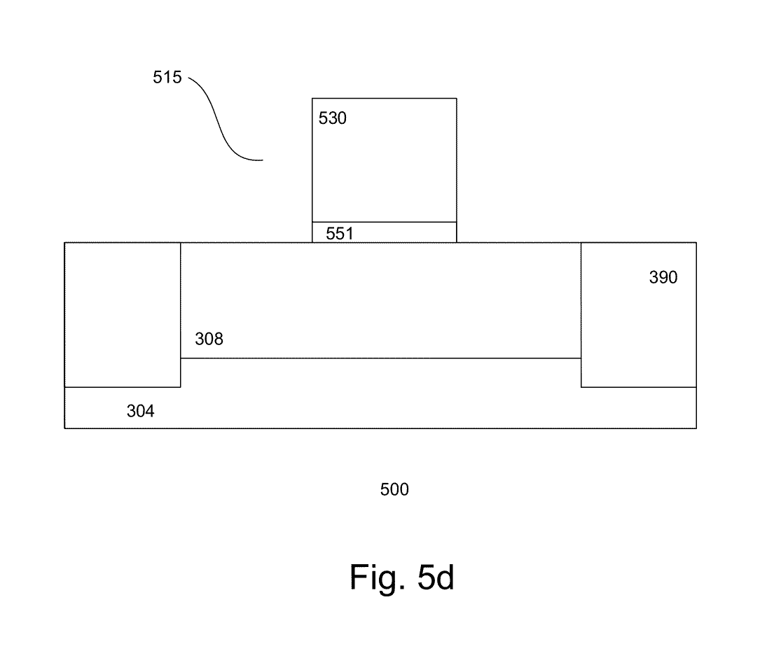

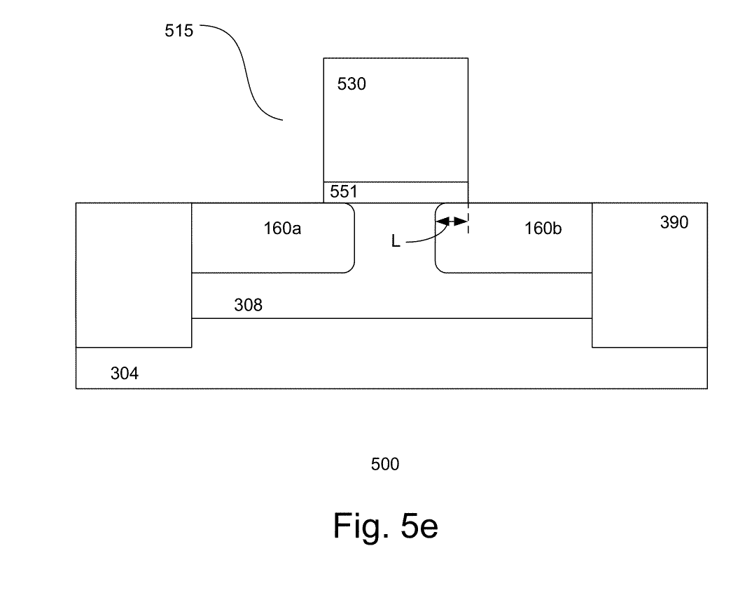

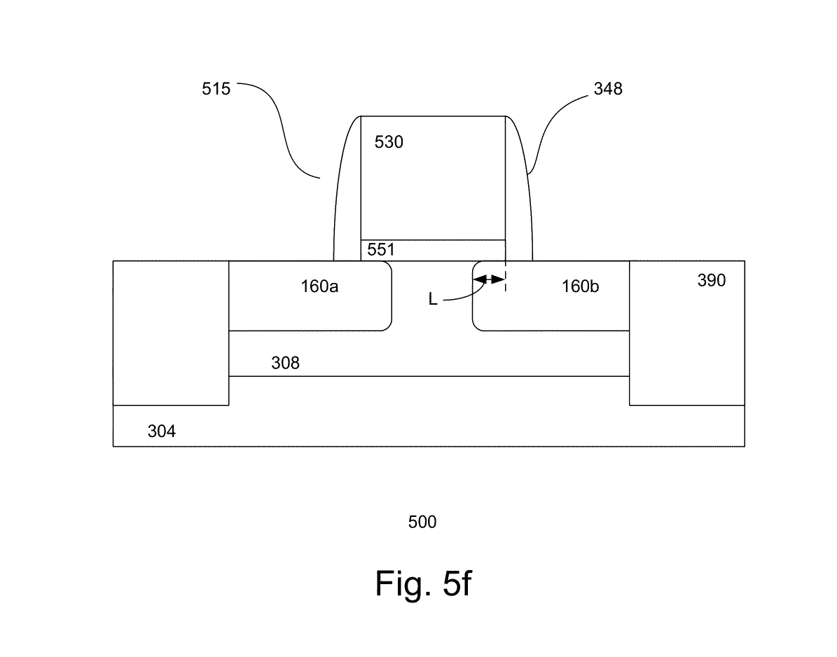

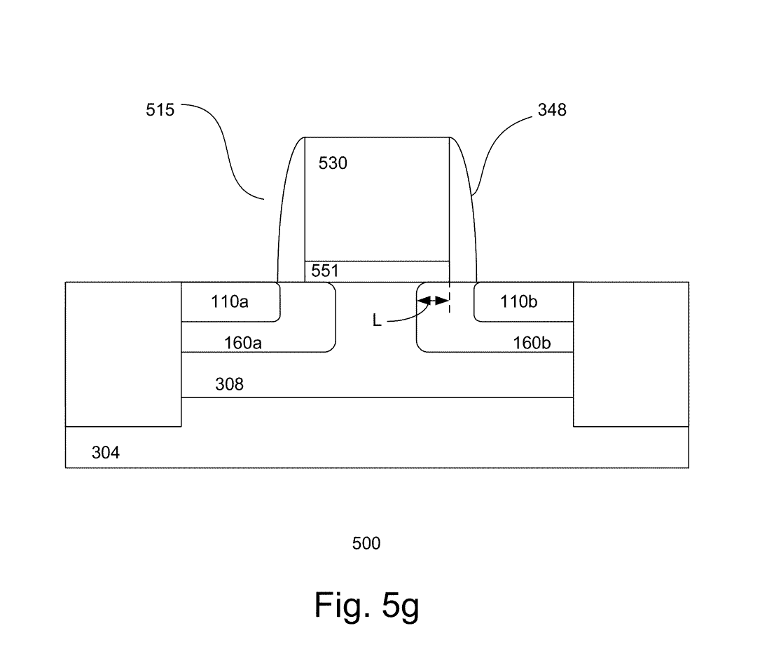

FIGS. 5a-h show cross-sectional views of an embodiment of a process for forming a portion of a device or IC. Referring to FIG. 5a, a substrate 304 is provided. The substrate can include a silicon substrate, such as lightly p-type doped substrate. N-type or other types of substrates, including semiconductor-on-insulator substrates, may also useful.

The substrate is prepared with a device region 306. The device region, in one embodiment, serves as a cell region for a memory cell. In one embodiment, the cell region serves as a device region of a dual-bit RRAM cell. The substrate is prepared with an isolation region 390. The isolation region serves to isolate the cell region from other device regions. In one embodiment, the isolation region includes a shallow trench isolation (STI) region. The STI region, for example, may have a depth of about 300 nm and a width of about 80 nm. Other dimensions for the STI region as well as other types of isolation regions may also be useful. Various processes can be employed to form the STI region. For example, the substrate can be etched using etch and mask techniques to form trenches which are then filled with dielectric materials such as silicon oxide. Chemical mechanical polishing (CMP) can be performed to remove excess oxide and provide a planar substrate top surface. Other processes or materials can also be used to form the STI.

As shown, the substrate includes one device region. It is, however, understood that the substrate may include a plurality of device regions. For example, numerous cell regions may be provided in an array region to form a plurality of memory cells. In some cases, one memory cell may occupy one cell region. For example, an isolation region may surround a cell region. Other configurations of memory cells, device regions, and isolation regions may also be useful. For example, isolation regions may be used to isolate bitlines of adjacent memory cells and adjacent gates of adjacent rows. In such a case, isolation regions may be provided to partially surround the cell region on all sides of the cell but does not completely surround it.

As shown in FIG. 5b, a deep well 308 is formed in the substrate. In one embodiment, the deep well is formed by implantation. The deep well includes second polarity type dopants. The deep well serves as a device well of the memory cell. The deep well, for example, has a depth which is shallower than the STI region. In one embodiment, the deep well is about 200 nm deep. Other depths for the deep well may also be useful. In some cases, a deep well extend below a bottom of the STI region may also be useful. In some embodiments, no deep well is provided. In such cases, the starting substrate may already be appropriately doped to serve as a deep well.

Refer to FIG. 5c, various layers of the gate are formed on the substrate. In one embodiment, a programmable resistive layer 551 is formed on the substrate.

The programmable resistive layer is formed of a material which can be programmed to be in a first or second resistive state after it has been subjected to a forming process. In one embodiment, the programmable resistive layer is formed of a transitional metal oxide, such as TiOₓ, NiOx, AlOx, HfOx, WOx, TaOx, VOx, and CuOx. Other types of programmable resistive layers may also be useful. The programmable resistive layer is formed by, for example, chemical vapor deposition (CVD), atomic layer deposition (ALD) and other methods. The thickness of the programmable resistive layer may be about 1-100 nm. Other techniques for forming or other thicknesses may also be useful for the programmable resistive layer.

A gate electrode layer 530 is deposited on the programmable resistive layer. The gate electrode layer may serve as a top electrode of a memory cell. The gate electrode, for example, comprises polysilicon. Other types of gate electrode materials, such as metal or metal nitride, are also useful. Various types of metal, such as Ti, Cu, Ta and W, can be used. Other types of gate electrode materials may also be useful. The thickness of the gate electrode can be about 80 nm. Other thicknesses may also be useful. Various techniques can be used to form the gate electrode layer. For example, polysilicon can be deposited by CVD while metal can be deposited by sputtering. Other processes for forming other types of gate electrode may also be useful.

Furthermore, the gate electrode 530 may be doped with dopants. The gate electrode, for example, may be doped with the same dopant type of the memory cell type. Doping the gate electrode with other dopant types is also useful.

In FIG. 5d, the gate layers are processed to form a gate. In one embodiment, the gate layers are patterned to form a gate conductor. The gate conductor may traverse other cell regions. In other embodiments, the gate layers are patterned to form an individual gate in the cell region. The patterning of the gate layers can be achieved, for example, by mask and etch techniques. For example, a patterned photoresist mask may be used as an etch mask for an anisotropic etch, such as a reactive ion etch (RIE). To improve lithographic resolution, an ARC can be provided beneath the photoresist. Other techniques for patterning the gate layers may also be useful. After patterning the gate layers, the mask, including the ARC layer, may be removed.

Referring to FIG. 5e, the substrate is implanted with dopants to form first doped regions 160a-b in the cell region. The first doped regions may serve as bottom electrodes of the memory cell. In one embodiment, first polarity type dopants are implanted into the substrate to form the first doped regions. In one embodiment, the first doped regions are lightly doped with first polarity type dopants. The dopant concentration of the lightly doped regions, for example, is about 1E13-1E15 cm⁻³. The first polarity type dopants may be p-type. Forming n-type doped regions may also be useful. In one embodiment, the dopants are implanted to form first doped regions which the gate overlaps, forming overlap portions adjacent to first and second sides of the gate. The first and second sides of the gate, for example, are along the bitline direction of the memory cell.

The overlap portions have a width L. In one embodiment, L is sufficiently small or narrow to limit the amount of filaments which are subsequently formed in the resistor portion of the programmable resistive layer to improve resistance distribution of memory bits. The smaller the L is, the smaller the number of filament current paths which are formed. For example, L may be about 1-10 nm in length, as measured from the edge of the first doped region and the overlapping gate sidewall. Such a width limits a low number of filaments to be formed in the resistor portion of the resistive layer. In one embodiment, L limits the number of filaments formed to 1-2. Providing L which limits other low number of filaments in the resistor portion of resistive layer may also be useful.

To form overlapping doped regions, angle implants may be used. For example, a first angle implant is used to form the first doped region 160a on the first side of the gate and a second angle implant is used to form the first doped region 160b on the second side of the gate. The implant angle θ of the implant can be in a range of about 1-20°. Other implant angles may also be useful. The implant conditions can be varied depending on, for example, the width of region L. For example, the angle, dose and energy can be selected to achieve the desired profile of the first doped regions. Additionally, dopant diffusion due to subsequent thermal processes, such as annealing to activate the dopants, is taken into account to determine the dopant profile of the first doped regions.

In FIG. 5f, sidewall spacers 348 may be formed on the sidewalls of the gate structure. In one embodiment, a spacer dielectric layer is deposited over the substrate. The spacer dielectric layer can be formed by using various techniques, such as plasma enhanced chemical vapor deposition (PECVD). Other techniques to form the spacer dielectric layer are also useful. The spacer dielectric layer is subsequently anisotropically etched, such as by reactive ion etching (RIE), to remove horizontal portions, leaving non-horizontal portions on sidewalls as spacers. The thickness of the spacers may be, for example, about 10-30 nm. Other thicknesses may also be useful.

Refer to FIG. 5g, second doped regions 110a-b are formed in the substrate adjacent to the sides of the gate. The second doped regions include second polarity type dopants. For example, the second doped regions have the opposite dopant type of the first doped regions. In one embodiment, the second doped regions are heavily doped with second polarity type dopants. For example, the second doped regions are heavily doped n-type regions for the case where the first doped regions are p-type regions. The dopant concentration of the second doped regions may be about 1E13-1E15 cm⁻³. Providing other dopant concentrations for the second doped regions may also be useful. In one embodiment, the second doped regions are formed by ion implantation. The implant parameters are selected to form the second doped regions a depth shallower than that of the first doped regions. Furthermore, dopants from the implant should not penetrate the gate electrode. The second doped regions are self-aligned to the spacers, gate and isolation regions.

In another embodiment, the second doped regions are formed of epitaxial layers on the substrate. The epitaxial layers may be silicon, germanium or a combination thereof. Other types of epitaxial layers may also be useful. The epitaxial layers may be grown on exposed surfaces of the substrate by selective epitaxial growth (SEG). For example, the epitaxial layers are self-aligned to the isolation regions and spacers. In other embodiments, trenches may be formed in the exposed surfaces of the substrate and epitaxial layers are formed in the trenches.

In one embodiment, the second doped regions are elevated. The epitaxial layers, in one embodiment, are insitu doped. Doping the epitaxial layers by ion implantation may also be useful. The dopants may be activated by, for example, annealing. The annealing, for example, may be rapid thermal annealing. Other types of thermal processes for activating the dopants may also be useful. For example, the annealing may include laser annealing.

The process may continue to complete the memory cell. For example, metal silicide contacts may be formed on the gate electrode and second doped regions. The metal silicide contacts, for example, may be nickel-based metal silicide contact. Other types of metal silicide contacts may also be useful. The metal silicide contacts facilitate reduced contact resistance. To form silicide contacts, a metal layer may be deposited over the substrate and annealed to cause a reaction with silicon. Unreacted metal are removed by, for example, a wet etch, leaving the silicide contacts on the gate electrode the second doped regions. Additional processes further include forming bitline contacts, wordline contacts, bitlines and wordlines. Other processes may also be included to complete the memory cell or device.

As described, the patterning of the gate layers forms individual gates. In other embodiment, the patterning of gate layers may form gate conductors. For example, the gate conductors traverse other cell regions.

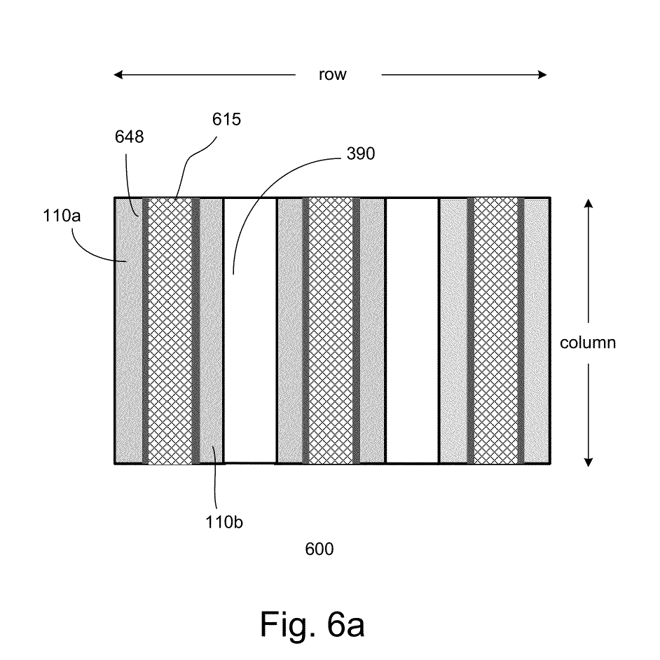

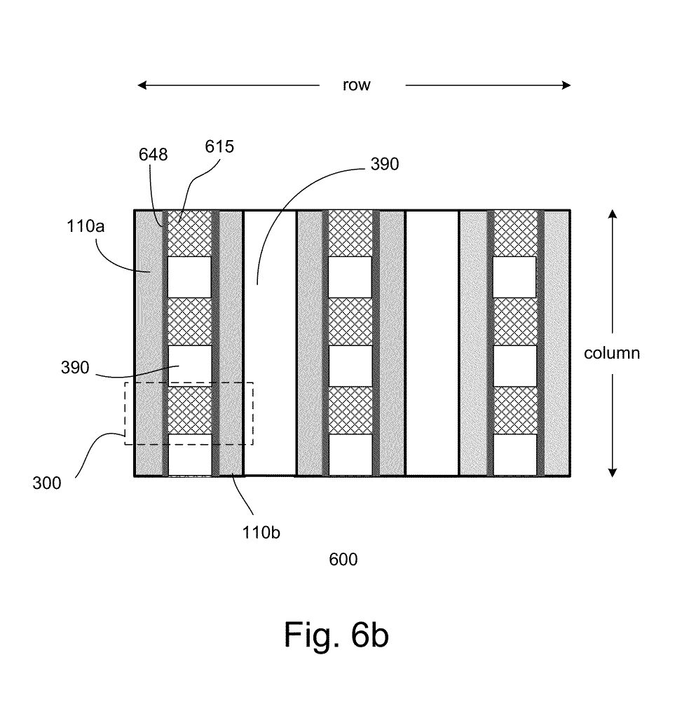

FIGS. 6a-b show plan views of an alternative process 600 for forming memory cells. Referring to FIG. 6a, the gate layers, as described in FIG. 5c, are patterned to form gate conductors 615 along a column direction of a memory array. The gate conductors are in cell regions along a column direction of the memory array. The cell regions are isolated by isolation regions 390 in the column direction.

The process continues as described in FIGS. 5e-g. For example, first doped regions are formed adjacent to first and second sides of the gate conductors to serve as bottom electrodes of the memory cells, sidewall spacers 648 are formed on first and second sides of the gate conductors, second doped regions 110a-b are formed adjacent to the first and second sides of the gate conductors and the substrate is annealed to activate the dopants of the doped regions.

Referring to FIG. 6b, the gate conductors are patterned to form individual gates of memory cells 300. The gate conductors may be patterned using mask and etch techniques, as previously described with respect to pattern the gate layers.

The process may continue to complete the memory cells. For example, metal silicide contacts may be formed on the gate electrodes and second doped regions. The metal silicide contacts, for example, may be nickel-based metal silicide contact. Other types of metal silicide contacts may also be useful. The metal silicide contacts facilitate reduced contact resistance. To form silicide contacts, a metal layer may be deposited over the substrate and annealed to cause a reaction with silicon. Unreacted metal are removed by, for example, a wet etch, leaving the silicide contacts on the gate electrode the second doped regions. Additional processes further include forming bitline contacts, wordline contacts, bitlines and wordlines. Other processes may also be included to complete the memory cell or device. Other processes to complete the device, for example, may include forming additional interconnects, passivation, dicing and packaging. Depending on the type of device, other processes may be included.

The invention may be embodied in other specific forms without departing from the spirit or essential characteristics thereof. The foregoing embodiments, therefore, are to be considered in all respects illustrative rather than limiting the invention described herein. Scope of the invention is thus indicated by the appended claims, rather than by the foregoing description, and all changes that come within the meaning and range of equivalency of the claims are intended to be embraced therein.

1. A device comprising:
a gate disposed on a substrate in a device region, the gate having first and second sidewalls, the gate includes a gate electrode and a resistive layer disposed between the gate electrode and substrate;
first doped regions of a first polarity type disposed in the substrate adjacent to the first and second sidewalls of the gate, wherein the gate overlaps the first doped regions by a first distance to form overlap portions; and
wherein a portion of the resistive layer between the gate electrode and overlap portions form first and second storage elements of a multi-bit resistive memory cell.

2. The device in claim 1 wherein the first distance is short enough to form a low number of conduction paths in the resistive layer when an appropriate voltage is applied.

3. The device in claim 2 wherein the number of conduction paths is about 1-2.

4. The device in claim 2 wherein the first distance is about 1-10 nm.

5. The device in claim 1 comprises first and second sidewall spacers on the first and second sidewalls of the gate.

6. The device in claim 5 comprises second doped regions of a second polarity type disposed in the substrate adjacent to first and second sidewall spacers of the gate.

7. The device in claim 6 wherein the second doped regions are disposed within the first doped regions.

8. The device in claim 1 comprises a deep well of a second polarity type disposed in the substrate encompassing the first and second doped regions.

9. The device in claim 1 wherein the gate is coupled to a wordline.

10. The device in claim 1 wherein the second doped regions are coupled to first and second bitlines.

11. A method of forming a device comprising:
providing a substrate;
forming a gate disposed on the substrate, the gate having first and second sidewalls, the gate includes a gate electrode and a resistive layer disposed between the gate electrode and substrate; and
forming first doped regions of a first polarity type disposed in the substrate adjacent to the first and second sidewalls of the gate, wherein the first doped regions overlap the gate by a first distance to form overlap portions, a portion of the resistive layer between the gate electrode and overlap portions form first and second storage elements of a multi-bit resistive memory cell.

12. The method in claim 11 wherein the first distance is short enough to form a low number of conduction paths in the resistive layer when an appropriate voltage is applied.

13. The method in claim 12 wherein the number of conduction paths is about 1-2.

14. The method in claim 12 wherein the first distance is about 1-10 nm.

15. The method in claim 11 comprises forming first and second sidewall spacers on the first and second sidewalls of the gate.

16. The method in claim 15 comprises forming second doped regions of a second polarity type disposed in the substrate adjacent to first and second sidewall spacers of the gate.

17. The method in claim 16 wherein the second doped regions are disposed within the first doped regions.

18. The method in claim 11 comprises forming a deep well of a second polarity type disposed in the substrate encompassing the first and second doped regions.

19. The method in claim 11 wherein the gate is coupled to a wordline and the second doped regions are coupled to first and second bitlines.

20. A device comprising:
a substrate prepared with a feature thereover, wherein the feature comprising a top electrode over a resistive layer; and
a doped region in the substrate adjacent to the feature, the doped region partially overlaps the resistive layer, wherein the doped region serves as a bottom electrode, the overlapping area is small enough to form low number of conduction paths in the resistive layer when an appropriate voltage is applied.
